(19) United States
(12) Patent Application Publication
(10) Pub. No.: US 2023/0274911 A1
(43) Pub. Date: Aug. 31, 2023

(54) ADJUSTABLE GEOMETRY TRIM COIL

(71) Applicant: Lam Research Corporation, Fremont, CA (US)

(72) Inventor: Andrew D. Bailey, III, Milpitas, CA (US)

(21) Appl. No.: 18/013,477

(22) PCT Filed: Jun. 24, 2021
(86) PCT No.: PCT/US2021/038980

§ 371 Date: Dec. 28, 2022

Related U.S. Application Data
(60) Provisional application No. 63/049,924, filed on Jul. 9, 2020.

(51) Int. Cl. H01J 37/32

(52) U.S. Cl. CPC H01J 37/32091; H01J 37/3266; H01J 37/32651; H01J 2237/3343; H01J 2237/184

(57) ABSTRACT

Methods, systems, apparatuses, and computer programs are presented for controlling etch rate and plasma uniformity using magnetic fields. A substrate processing apparatus includes a vacuum chamber including a processing zone for processing a substrate. The apparatus further includes a magnetic field sensor configured to detect a signal representing a residual magnetic field associated with the vacuum chamber. At least one magnetic field source is configured to generate one or more supplemental magnetic fields through the processing zone of the vacuum chamber. A magnetic field controller is coupled to the magnetic field sensor and the at least one magnetic field source. The magnetic field controller is configured to adjust at least one characteristic of the one or more supplemental magnetic fields, causing the one or more supplemental magnetic fields to reduce the residual magnetic field to a pre-determined value.

### CLAIM OF PRIORITY

This application claims the benefit of priority to U.S. Patent Application Ser. No. 63/049,924, filed on Jul. 9, 2020, which is incorporated by reference herein in its entirety.

### TECHNICAL FIELD

The subject matter disclosed herein generally relates to methods, systems, and machine-readable storage media for controlling etch rate and plasma uniformity using magnetic fields in a capacitively coupled plasma (CCP) used in semiconductor manufacturing, wherein the magnetic fields are generated by an adjustable geometry trim coil.

### BACKGROUND

Substrate processing apparatuses are used to process substrates (e.g., semiconductor substrates) by techniques including etching, physical vapor deposition (PVD), chemical vapor deposition (CVD), plasma-enhanced chemical vapor deposition (PECVD), atomic layer deposition (ALD), plasma-enhanced atomic layer deposition (PEALD), pulsed deposition layer (PDL), plasma-enhanced pulsed deposition layer (PEPDL), and resist removal. One type of substrate processing apparatus is a plasma processing apparatus using CCP that includes a vacuum chamber containing upper and lower electrodes, where a radio frequency (RF) power is applied between the electrodes to excite a process gas into plasma for processing substrates in the reaction chamber.

In substrate processing apparatuses, such as the CCP-based vacuum chambers for manufacturing substrates, etch uniformity and ion tilt at the substrate are influenced by plasma density uniformity, which has shown sensitivity to weak magnetic fields. For example, plasma density uniformity in CCP-based vacuum chambers can be influenced by magnetic fields associated with magnetized chamber components (which may be associated with a magnetic field strength of 5-10 Gauss) as well as other external magnetic fields including the Earth's magnetic field (which may have a magnetic field strength of 0.25-0.65 Gauss) or other ambient magnetic fields (which may have a magnetic field strength of 0.4-0.5 Gauss).

Currently, controlling plasma uniformity, particularly at the center of the substrate, is a challenge due to residual magnetic fields inside the chamber. Changing the dimension of the ground electrode within the chamber, gas and chemistry flows or the frequency content of delivered radio frequency (RF) are the main factors used to control uniformity. However, the magnetization of processing chamber components, as well as exposure to external magnetic fields, causes residual magnetic fields within the chamber, which influences plasma density uniformity and varies greatly from chamber to chamber within a manufacturing location, as well as between chambers at different manufacturing locations. The present disclosure seeks to address, amongst other things, the drawbacks associated with conventional techniques for plasma density uniformity including the drawbacks of residual magnetic fields.

The background description provided herein is to generally present the context of the disclosure. It should be noted that the information described in this section is presented to provide the skilled artisan some context for the following disclosed subject matter and should not be considered as admitted prior art. More specifically, work of the presently named inventors, to the extent it is described in this background section, as well as aspects of the description that may not otherwise qualify as prior art at the time of filing, are neither expressly nor impliedly admitted as prior art against the present disclosure.

### SUMMARY

Methods, systems, and computer programs are presented for controlling etch rate and plasma uniformity using magnetic fields of an adjustable geometry trim coil during semiconductor manufacturing. One general aspect includes a substrate processing apparatus. The apparatus includes a vacuum chamber, a magnetic field sensor, an adjustable geometry trim coil (AGTC), and a magnetic field controller. The vacuum chamber includes a processing zone for processing a substrate using capacitively coupled plasma (CCP). The magnetic field sensor is configured to detect a residual magnetic field within the vacuum chamber. The AGTC is configured to generate a supplemental magnetic field through the processing zone of the vacuum chamber. The magnetic field controller is coupled to the magnetic field sensor and the AGTC. The magnetic field controller is configured to adjust at least one parameter of the AGTC, causing the supplemental magnetic field to reduce the residual magnetic field to a pre-determined value.

One general aspect includes a method for processing a substrate using a vacuum chamber. The method includes detecting a residual magnetic field within a processing zone of the vacuum chamber. The processing zone for processing the substrate. The method includes determining a magnitude of the residual magnetic field. At least one parameter of an AGTC is adjusted based on the determined magnitude of the residual magnetic field. A supplemental magnetic field through the processing zone of the vacuum chamber is generated using the AGTC, the supplemental magnetic field reducing the residual magnetic field to a pre-determined value.

One general aspect includes a non-transitory machine-readable storage medium including instructions that, when executed by a machine, cause the machine to perform operations including detecting a residual magnetic field within a processing zone of a vacuum chamber, the processing zone for processing the substrate. Executing the instructions further causes the machine to determine the magnitude of the residual magnetic field. Executing the instructions further causes the machine to adjust at least one parameter of an AGTC based on the determined magnitude of the residual magnetic field. Executing the instructions further cause the machine to generate a supplemental magnetic field through the processing zone of the vacuum chamber using the AGTC, the supplemental magnetic field reducing the residual magnetic field to a pre-determined value.

### BRIEF DESCRIPTION OF THE DRAWINGS

Various ones of the appended drawings merely illustrate example embodiments of the present disclosure and cannot be considered as limiting its scope.

FIG. 1 illustrates a vacuum chamber, such as an etching chamber, for manufacturing substrates using CCP, according to an example embodiment.

FIG. 2 illustrates a vacuum chamber enclosed by a magnetic shield structure to improve control of etch rate and plasma uniformity, according to an example embodiment.

FIG. 3A illustrates a perspective view of a vacuum chamber with a residual magnetic field within a processing zone with CCP, according to an example embodiment.

FIG. 3B illustrates a top view of the vacuum chamber of FIG. 3A, according to an example embodiment.

FIG. 3C illustrates a side view of the vacuum chamber of FIG. 3A, according to an example embodiment.

FIG. 4 illustrates an example of an adjustable geometry trim coil (AGTC), according to an example embodiment.

FIG. 5 illustrates a tension maintaining assembly which can be used with the AGTC of FIG. 4, in an example embodiment.

FIG. 6A and FIG. 6B illustrate example configurations of the AGTC of FIG. 4 using different coil geometries, in an example embodiment.

FIG. 7A illustrates a perspective view of a vacuum chamber with an AGTC used as a magnetic field source to counteract a residual magnetic field, according to an example embodiment.

FIG. 7B is a side view of the vacuum chamber of FIG. 7A and illustrates mounting options for the AGTC, according to an example embodiment.

FIG. 8 illustrates a perspective view of a vacuum chamber with multiple AGTCs configured as a Helmholtz pair generating a magnetic field to counteract a residual magnetic field, according to an example embodiment.

FIG. 9 illustrates a perspective view of a vacuum chamber with multiple AGTCs configured as multiple Helmholtz pairs generating multiple magnetic fields to counteract a residual magnetic field, according to an example embodiment.

FIG. 10 illustrates a top view of a vacuum chamber using multiple pairs of AGTCs generating different magnetic fields to counteract a residual magnetic field, according to an example embodiment.

FIG. 11 illustrates a vacuum chamber with different types of magnetic sensors and a magnetic field controller to configure one or more supplemental magnetic fields that counteract a residual magnetic field, according to an example embodiment.

FIG. 12 illustrates an arrangement of vacuum chambers in a manufacturing facility that can use the disclosed techniques to reduce, zero out, or make uniform multiple residual magnetic fields within the vacuum chambers, according to an example embodiment.

FIG. 13 is a flowchart of a method for processing a substrate using magnetic fields in semiconductor manufacturing equipment, according to an example embodiment.

FIG. 14 is a block diagram illustrating an example of a machine upon which one or more example method embodiments may be implemented, or by which one or more example embodiments may be controlled.

### DETAILED DESCRIPTION

Example methods, systems, and computer programs are directed to controlling etch rate and plasma uniformity using magnetic fields in CCP-based semiconductor manufacturing equipment. Examples merely typify possible variations. Unless explicitly stated otherwise, components and functions are optional and may be combined or subdivided, and operations may vary in sequence or be combined or subdivided. In the following description, for purposes of explanation, numerous specific details are set forth to provide a thorough understanding of example embodiments. It will be evident to one skilled in the art, however, that the present subject matter may be practiced without these specific details.

The center of substrate uniformity is challenging to control since it depends on etch process conditions. When conditions change, uniformity may change as well. Static solutions to control the center of wafer uniformity (such as adjusting the ground electrode dimension) may not perform efficiently over a wide range of process conditions. Solutions involving process parameters may lead to unwanted side effects when modified to address uniformity.

Techniques discussed herein use supplemental magnetic fields generated by an adjustable geometry trim coil (AGTC) to control residual magnetic fields within the vacuum chamber that may influence etch rate and center of substrate plasma uniformity. More specifically, one or more AGTCs may be used to generate corresponding one or more supplemental (or trim) magnetic fields to counteract the residual magnetic field within the vacuum chamber. In an example embodiment, one or more magnetic field sensors may be used to detect the residual magnetic field (ΔB) within the processing zone of the vacuum chamber. For example, the magnetic sensors may detect a vertical component (Bz) as well as a horizontal component (Bh) of the residual magnetic field. In some aspects, the magnetic sensors may detect a magnitude and a direction of the residual magnetic field (which may be determined based on magnitude and direction of each of the vertical component and horizontal component of the residual magnetic field) and correspondingly adjust one or more parameters of an AGTC (e.g., the geometry of the AGTC, a perimeter length of a coil conductor wire forming the AGTC, and current through the coil conductor wire).

In an example embodiment, techniques disclosed herein can use a sensor to detect non-uniformity of a metric of a substrate surface before the substrate processing (e.g., a non-uniformity of a lithographic mask of the substrate or non-uniformity of sub-micron features of the substrate) or post-processing. An AGTC may be configured (e.g., by configuring the geometry of the AGTC, the perimeter length of a coil conductor wire forming the AGTC, and the current through the coil conductor wire) to generate a magnetic field based on the detected non-uniformity (e.g., a non-uniform mask) so that a non-uniform etch corresponding to the non-uniform mask is achieved after the substrate is processed, resulting in a uniform substrate surface after processing. In an example embodiment, configuring parameters of the AGTC based on the detected non-uniformity can be performed independently of (and can be prioritized over) any detected residual magnetic field. In an example embodiment, at least one AGTC can be configured to counter (e.g., reduce) a residual magnetic field, while at least another (e.g., a second) AGTC can be used to trigger a non-uniform etch based on detected non-uniformity of a metric of the substrate surface.

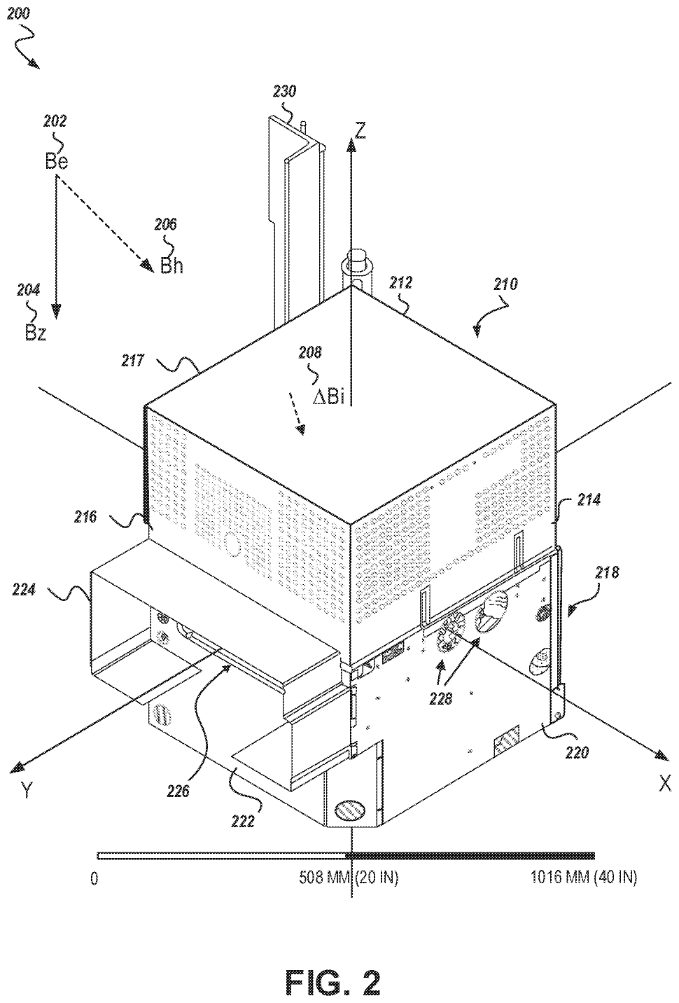

Various techniques and options for configuring the magnetic shield structure as well as the at least one magnetic field source are illustrated in connection with FIG. 2-FIG. 14.

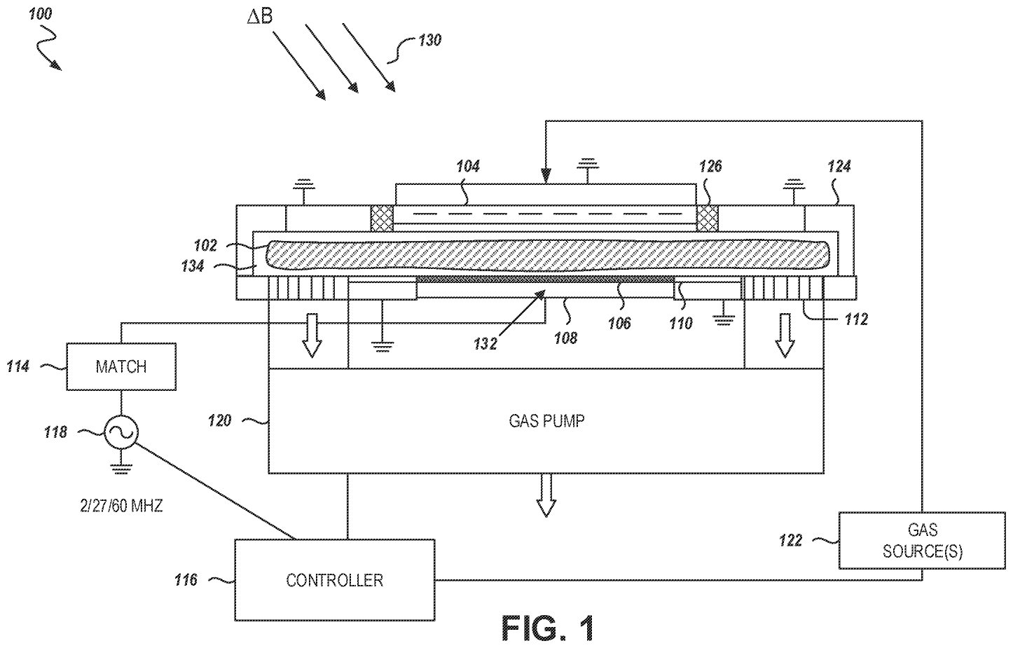

FIG. 1 illustrates a vacuum chamber 100 (e.g., an etching chamber) for manufacturing substrates using CCP, according to one embodiment. Exciting an electric field between two electrodes is one of the methods to obtain radio frequency (RF) gas discharge in a vacuum chamber. When an oscillating voltage is applied between the electrodes, the discharge obtained is referred to as a CCP discharge.

Plasma 102 may be created utilizing stable feedstock gases to obtain a wide variety of chemically reactive by-products created by the dissociation of the various molecules caused by electron-neutral collisions. The chemical aspect of etching involves the reaction of the neutral gas molecules and their dissociated by-products with the molecules of the to-be-etched surface and producing volatile molecules, which can be pumped away. When a plasma is created, the positive ions are accelerated from the plasma across a space-charge sheath separating the plasma from chamber walls to strike the wafer surface with enough energy to remove material from the wafer surface. This is known as ion bombardment or ion sputtering. Some industrial plasmas, however, do not produce ions with enough energy to efficiently etch a surface by purely physical means.

A controller 116 manages the operation of the vacuum chamber 100 by controlling the different elements in the chamber, such as RF generator 118, gas sources 122, and gas pump 120. In one embodiment, fluorocarbon gases, such as CF₄ and C₄F₈, are used in a dielectric etch process for their anisotropic and selective etching capabilities, but the principles described herein can be applied to other plasma-creating gases. The fluorocarbon gases are readily dissociated into chemically reactive by-products that include smaller molecular and atomic radicals. These chemically reactive by-products etch away the dielectric material.

The vacuum chamber 100 illustrates a processing chamber with atop electrode 104 and a bottom electrode 108. The top electrode 104 may be grounded or coupled to an RF generator (not shown), and the bottom electrode 108 is coupled to the RF generator 118 via a matching network 114. The RF generator 118 provides RF power in one or multiple (e.g., two or three) different RF frequencies. According to the desired configuration of the vacuum chamber 100 for a particular operation, at least one of the three RF frequencies may be turned on or off. In the embodiment shown in FIG. 1, the RF generator 118 is configured to provide, e.g., 2 MHz, 27 MHz, and 60 MHz frequencies, but other frequencies are also possible.

The vacuum chamber 100 includes a gas showerhead on the top electrode 104 to input gas into the vacuum chamber 100 provided by the gas source(s) 122, and a perforated confinement ring 112 that allows the gas to be pumped out of the vacuum chamber 100 by gas pump 120. In an example embodiment, the gas pump 120 is a turbomolecular pump, but other types of gas pumps may be utilized.

When substrate 106 is present in the vacuum chamber 100, silicon focus ring 110 is situated next to substrate 106 such that there is a uniform RF field at the bottom surface of the plasma 102 for uniform etching on the surface of the substrate 106. The embodiment of FIG. 1 shows a triode reactor configuration where the top electrode 104 is surrounded by a symmetric RF ground electrode 124. Insulator 126 is a dielectric that isolates the ground electrode 124 from the top electrode 104. Other implementations of the vacuum chamber 100 are also possible without changing the scope of the disclosed embodiments.

The substrate 106 can include, for example, wafers (e.g., having a diameter of 100 mm, 150 mm, 200 mm, 300 mm, 450 mm, or larger) and comprising, for example, elemental-semiconductor materials (e.g., silicon (Si) or germanium (Ge)) or compound-semiconductor materials (e.g., silicon germanium (SiGe) or gallium arsenide (GaAs)). Additionally, other substrates include, for example, dielectric materials such as quartz or sapphire (onto which semiconductor materials may be applied).

Each frequency generated by the RF generator 118 may be selected for a specific purpose in the substrate manufacturing process. In the example of FIG. 1, with RF powers provided at, for example, 400 kHz and 60 MHz, with the 400 kHz RF power providing ion energy control, and the 60 MHz power providing control of the plasma density and the dissociation patterns of the chemistry. In an example embodiment, other RF powers may be used as well. In other embodiments, RF power may be provided to a primary electrode supporting the substrate or other electrodes to control the plasma properties. This configuration, where each RF power may be turned on or off, enables certain processes that use ultra-low ion energy on the substrates or wafers, and certain processes (e.g., soft etch for low-k materials) where the ion energy has to be low (e.g., under 700 or 200 eV).

In another embodiment, a 60 MHz RF power is used on the top electrode 104 to get ultra-low energies and very high density. This configuration allows chamber cleaning with high-density plasma when substrate 106 is not in the vacuum chamber 100 while minimizing sputtering on the electrostatic chuck (ESC) surface. The ESC surface is exposed when substrate 106 is not present, and any ion energy on the surface should be avoided, which is why the bottom 2 MHz and 27 MHz power supplies may be off during cleaning.

In some aspects, the vacuum chamber 100 is exposed to external magnetic fields, such as the Earth's magnetic field or other ambient magnetic fields (e.g., magnetic fields from magnetized components of the vacuum chamber such as a hoist as illustrated in FIG. 2) or similar components part of the building or nearby equipment. In this regard, the vacuum chamber 100 may be enclosed with a magnetic shield structure to reduce the residual magnetic field ΔB 130 that may penetrate the processing zone 134 of the vacuum chamber 100. The presence of the residual magnetic field 130 in the vacuum chamber 100 is undesirable as it may negatively impact etch rate and plasma uniformity, especially around a center region 132 of the substrate 106 within the processing zone 134. Various techniques using at least one AGTC to further reduce or zero out the residual magnetic field 130 are discussed in connection with FIG. 2-FIG. 14. Even though techniques and embodiments associated with AGTCs are discussed in connection with CCP-based substrate processing devices, the disclosure is not limited in this regard and disclosed techniques may be used in connection with other types of substrate processing devices.

FIG. 2 illustrates a vacuum chamber enclosed by a magnetic shield structure to improve control of etch rate and plasma uniformity, according to an example embodiment. Referring to FIG. 2, a vacuum chamber, such as vacuum chamber 100 of FIG. 1, may be enclosed by a magnetic shield structure 200 to reduce the effects of an external magnetic field (Be) 202, which includes a vertical component (Bz) 204 and a horizontal component (Bh) 206.

In an example embodiment, the magnetic shield structure 200 can include a top shielding portion 210 and a bottom shielding portion 218, where each shielding portion may include multiple shielding sub-portions as shown in FIG. 2. For example, the top shielding portion 210 can include shielding sub-portions 212, 214, 216, and 217. The bottom shielding portion 218 can include shielding sub-portions 220, 222, and 224. In some aspects, the magnetic shield structure 200 can include one or more openings 228 to accommodate various facilities used by the vacuum chamber, such as openings to accommodate RF components and communication links, ventilation, gas delivery, heaters, high-voltage clamps, substrate delivery mechanisms, etc.

In an example embodiment, the magnetic shield structure 200 can be manufactured from a high permeability material with a thickness of at least 40 mils. In an example embodiment, the various shielding sub-portions of the magnetic shield structure 200 can be bolted to (or securely attached via other means) to various surfaces of the vacuum chamber.

In an example embodiment, the shielding sub-portion 224 can be formed as a tunnel surrounding the vacuum chamber opening 226, which is used for delivery and removal of the substrate from the processing zone with the CCP.

Due to imperfections of the magnetic shield structure 200 (e.g., the one or more openings 228 for accommodating vacuum chamber facilities), a residual magnetic field (ΔB) 208 can exist under the magnetic shield structure 200 and within the vacuum chamber 100 as a result of the external magnetic field (Be) 202 as well as external magnetic fields from magnetized chamber components (e.g., a magnetized hoist 230). Since such residual magnetic field 208 is internal to the vacuum chamber 100, FIG. 2 references the residual magnetic field 208 as ΔBi. In an example embodiment, one or more supplemental magnetic fields may be generated using at least one AGTC within the vacuum chamber 100, where parameters (e.g., geometry, perimeter, and current) of the at least one AGTC are configured to counteract the effects of the residual magnetic field 208 (e.g., reduce or zero out a magnitude of the residual magnetic field 208 and/or change a direction of the residual magnetic field 208 to achieve uniformity among multiple shielded vacuum chambers at the same manufacturing location).

Additionally, any external magnetized chamber components (such as the hoist 230) can be demagnetized and/or shielded to further reduce the residual magnetic field 208. In some aspects, the hoist 230 can be magnetized in the order of 5-10 Gauss, which field can contribute to the residual magnetic field 208. More specifically, a particular magnetic field for a particular unshielded chamber can be estimated (e.g., a chamber in a particular geographic location in a particular fab running a particular recipe on a particular customer product's etched feature profile tilt metric). The magnetic material of hoist 230 can be magnetized to deliver the estimated value, and hence optimize the chamber to chamber matching.

Without the use of the magnetic shield structure 200, the residual magnetic field 208 may be in the magnitude of 0.5 Gauss in the vertical component (Bz) and 0.4 Gauss in the horizontal component (Bh). In some aspects, using the magnetic shield structure 200 can result in about 60% reduction of the residual magnetic field 208 (i.e., between 0.1 and 0.2 Gauss). In some aspects, by using one or more supplemental magnetic fields generated using the disclosed techniques, the residual magnetic field 208 within the vacuum chamber 100 may be reduced to below 0.1 Gauss.

In an example embodiment, an AGTC as discussed herein can be configured in proximity to (e.g., mounted in proximity to) the hoist 230. In this regard, the magnetic properties and the magnetic field-causing effect of the AGTC (coupled with a current-controlled power supply and/or a moving spool assembly with the fixed current) can result in a supplemental magnetic field in the proximity of the hoist 230, which can be used instead of magnetizing the hoist 230.

In an example embodiment, a shield may be used spatially around the AGTC to have a stable engineered magnetic circuit for the AGTC, e.g., in connection with introduced or necessary magnetic components such as the hoist or motor cores, etc.

In an example embodiment, the magnetization of the hoist 230 itself and/or the shielding structures of the chamber (e.g., 210, 218) and/or other flux plates may be used as (a) a source of magnetic perturbation or correction as well as (b) shield-like components that are part of the AGTC.

In an example embodiment, the magnetic shield structure 200 can be configured as a cubicle structure surrounding the vacuum chamber 100, with each side of the cubicle structure measuring about 584 mm (approximately 23 inches) to 711 mm (approximately 28 inches) in length. In an example embodiment, the vacuum chamber opening 226 may measure about 50 mm (approximately 2 inches) in height.

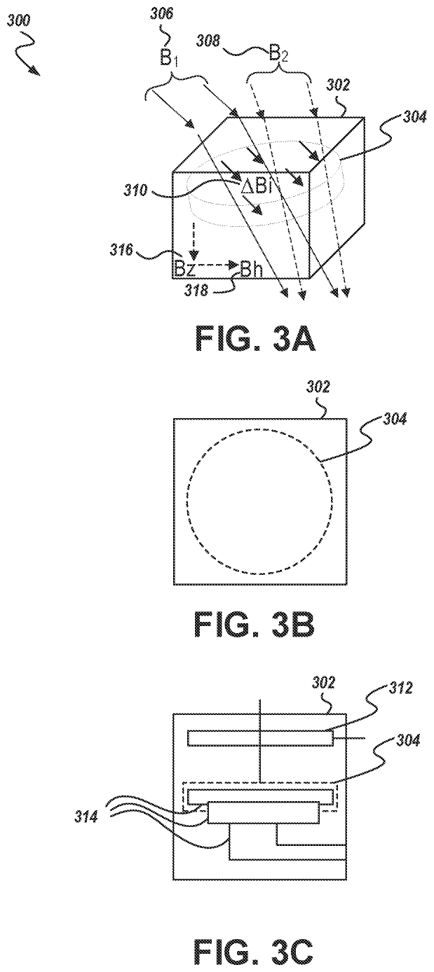

FIG. 3A illustrates a perspective view 300 of a vacuum chamber 302 with a residual magnetic field within a processing zone with CCP, according to an example embodiment. Referring to FIG. 3A, the vacuum chamber 302 can be exposed to a first external magnetic field 306 and a second external magnetic field 308. The vacuum chamber 302 may include a magnetic shield structure (e.g., a magnetic field structure such as magnetic shield structure 200 in FIG. 2), which is not visible in FIG. 3A.

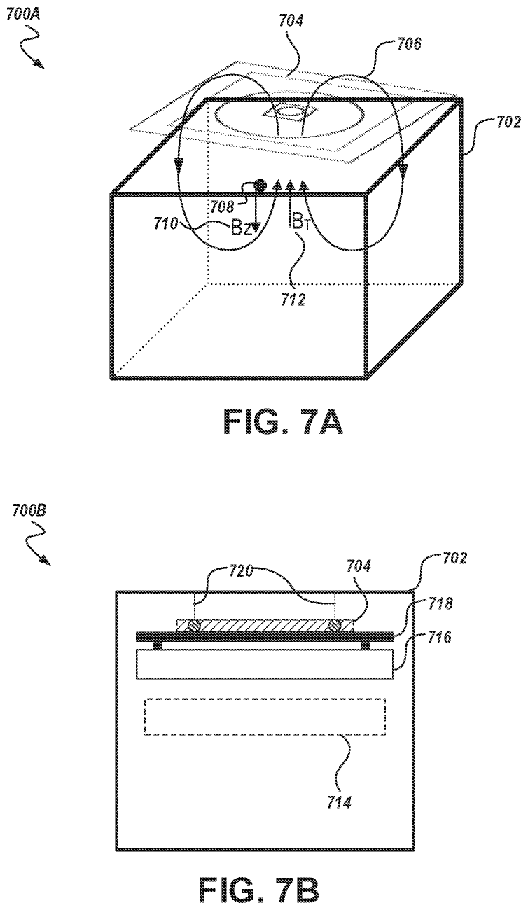

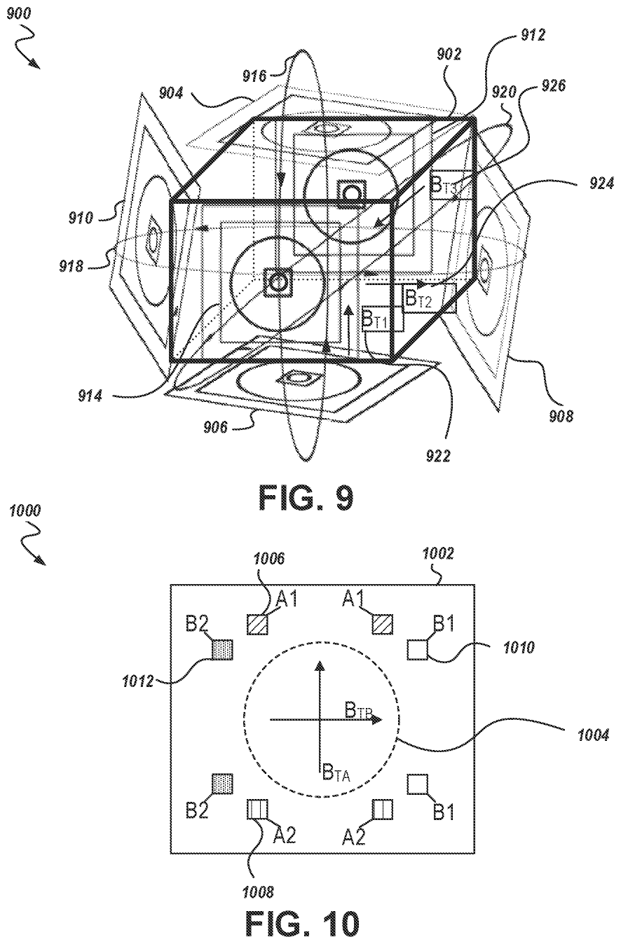

The vacuum chamber 302 includes a processing zone 304, which may be a volume filled with the CCP inside the vacuum chamber 302. The external magnetic fields 306 and 308 may penetrate the vacuum chamber 302, resulting in a residual magnetic field (ΔBi) 310. The residual magnetic field 310 may comprise a vertical component (Bz) 316 and a horizontal component (Bh) 318. In some aspects (e.g., as illustrated in FIG. 8), the horizontal component 318 may be zero and a supplemental magnetic field with only a vertical component can be generated within the vacuum chamber 302 to counteract the vertical component 316. In other aspects (e.g., as illustrated in FIG. 10), the vertical component 316 may be zero and a supplemental magnetic field with only a horizontal component can be generated within the vacuum chamber 302 to counteract the horizontal component 318.

FIG. 3B illustrates a top view of the vacuum chamber 302 of FIG. 3A, according to an example embodiment. FIG. 3C illustrates a side view of the vacuum chamber 302 of FIG. 3A, according to an example embodiment. Referring to FIG. 3C, the vacuum chamber 302 can include a top plate 312 as well as various facilities 314 used in connection with processing a substrate within the processing zone 304 (e.g., RF components and communication links, gas delivery mechanisms, heaters, high-voltage clamps, substrate delivery mechanisms, etc.). The top plate 312 can include thermo-couplers and auxiliary components to handle the gas flow, power for temperature control, mechanical components associated with gas vacuum functionalities, etc.

In an example embodiment, the top plate 312 or the facilities 314 may be used for mounting at least one magnetic field source (e.g., at least one AGTC) that can generate one or more supplemental magnetic fields to counter the residual magnetic field within the vacuum chamber 302. At least one AGTC may also be used to generate a magnetic field based on the non-uniform mask so that a non-uniform etch corresponding to the non-uniform mask is achieved after the substrate is processed, resulting in a uniform substrate surface after processing.

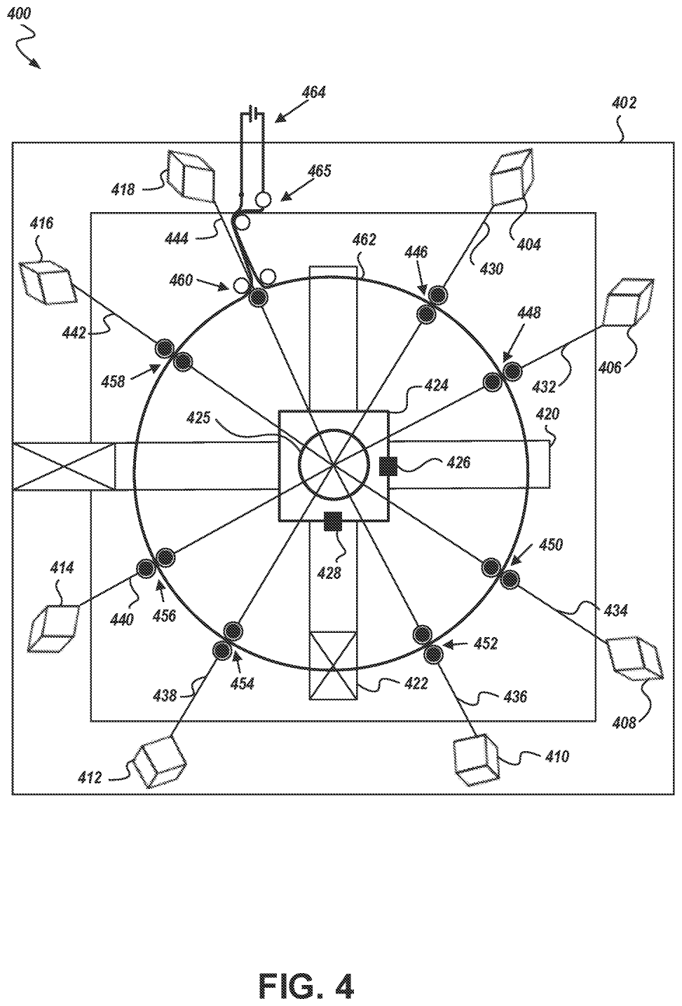

FIG. 4 illustrates an example adjustable geometry trim coil (AGTC) 400, according to an example embodiment. Referring to FIG. 4, the AGTC 400 includes a frame 402 with a plurality of tension adjustment assemblies 404, 406, 408, 410, 412, 414, 416, and 418. The frame 402 also supports a horizontal drive screw 420 which is mechanically coupled to a central spool assembly 424 and a vertical drive screw 422. The central spool assembly 424 includes a spool 425 and drive motors 426 and 428. Drive motor 426 may be used to move the vertical drive screw 422 with the central spool assembly 424 in a horizontal direction, along the horizontal drive screw 420. Drive motor 428 may be used to move the central spool assembly 424 in a vertical direction, along the vertical drive screw 422. Even though FIG. 4 illustrates a square frame 402, the disclosure is not limited in this regard and the frame 402 can be of other shapes as well, such as circular, rectangular, etc.

Each of the tension adjustment assemblies 404-418 is coupled to corresponding tension strings 430, 432, 434, 436, 438, 440, 442, and 444 respectively. Additionally, each of the tension adjustment assemblies 404-418 can include suitable circuitry, interfaces, or code configured to adjust the length (e.g., collect or release) of the corresponding tension strings 430-444. In example embodiments, each of the tension adjustment assemblies can include a motor, a spring, or another type of mechanism for adjusting the tension string length. Even though FIG. 4 illustrates two tension adjustment assemblies on each side of frame 402 the disclosure is not limited in this regard and the tension adjustment assemblies 404-418 can be placed in other configurations along portions of frame 402.

Tension strings 430, 432, 434, 436, 438, 440, 442, and 444 include corresponding perimeter guide roller sets 446, 448, 450, 452, 454, 456, 458, and 460 respectively. Each of the perimeter guide roller sets 446-460 is configured to support a coil conductor wire 462 which forms a coil within a frame 402. More specifically, each perimeter guide roller set can include two rollers (or other support structures) that support the coil conductor wire on opposite sides, allowing movement of the coil conductor wire when the corresponding tension string of the perimeter guide roller set moves within the frame 402. The coil conductor wire is supplied by a wire supply assembly 465 so that a different length of the coil conductor wire 462 can be configured and supported by each of the perimeter guide roller sets, thereby changing the perimeter length of the coil conductor wire 462 four different configurations of the AGTC 400. The coil conductor wire 462 is coupled to a voltage supply assembly 464 which can regulate voltage and current through the coil conductor wire 462.

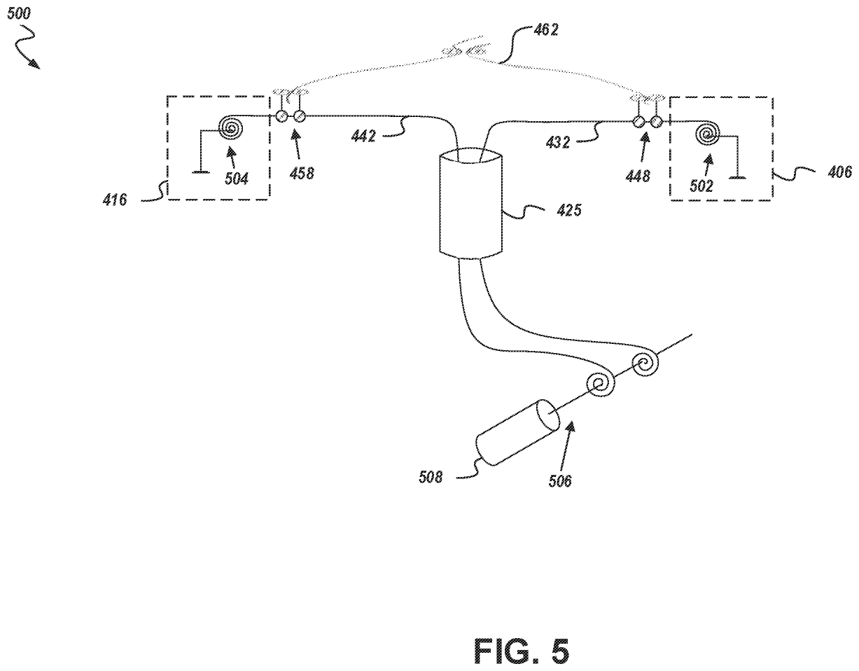

As illustrated in FIG. 4, one end of each of the tension strings 430 444 is attached to the corresponding tension adjustment assemblies 404-418, with the second end of each tension string being threaded through an opening of the spool 425 in the central spool assembly 424 and attached to a tension maintaining assembly 506 (illustrated in FIG. 5).

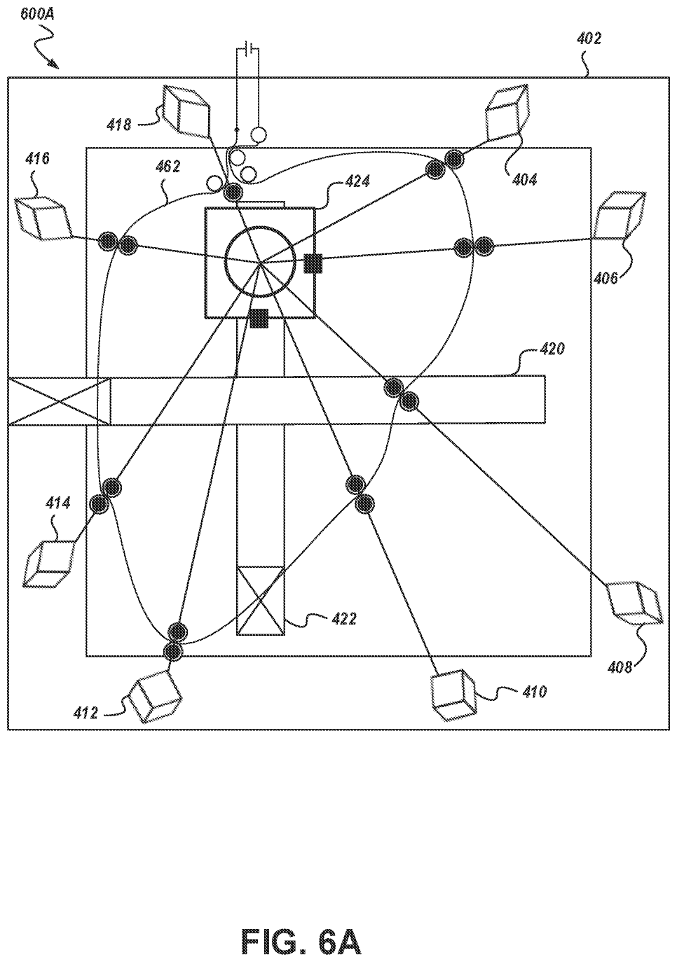

In operation, a substrate processing apparatus control circuitry (e.g., controller 116) can adjust the geometry AGTC 400 by positioning the central spool assembly 424 within a specific location enclosed by the frame 402 by moving the central spool assembly along the horizontal drive screw 420 and/or the vertical drive screw 422. Additionally, the geometry of the AGTC 400 can be adjusted by adjusting the length of each of the tension strings 430-444, which results in movement of the corresponding perimeter guide roller sets 446-460 and corresponding movement of the coil conductor wire 462 thereby configuring a unique geometry of the AGTC 400 (e.g., example geometries of the AGTC are illustrated in FIG. 6A and FIG. 6B). After the length of each tension string is adjusted by the tension adjustment assemblies 404-418, the opposite end of each tension string, which is threaded through the spool 425 of the central spool assembly 424, is coupled to the tension maintaining assembly 506 so that tension is maintained on each of the tension strings.

FIG. 5 illustrates diagram 500 of a tension maintaining assembly 506 which can be used with the AGTC of FIG. 4, in an example embodiment. Referring to FIG. 5, diagram 500 illustrates a perspective view of tension adjustment assemblies 406 and 416 of the AGTC 400, coupled to corresponding tension strings 432 and 442 respectively. As illustrated in FIG. 5, the coil conductor wire 462 is supported on opposite sides by perimeter guide roller sets 448 and 458.

In an example embodiment, tension adjustment assemblies 416 and 406 include corresponding drive motors 504 and 502 configured to collect or release the tension strings 442 and 432 at a first end of the strings. A second end of the strings is threaded through the spool 425 of the central spool assembly 424 and is coupled to the tension maintaining assembly 506, as illustrated in FIG. 5. In an example embodiment, the tension maintaining assembly 506 includes a tension mechanism 508, which can be a spring, a drive motor, or another mechanism. Even though the tension maintaining assembly 506 is illustrated as having a single tension mechanism 508, the disclosure is not limited in this regard and a separate tension mechanism can be used for each of the tension strings 430-444. In an example embodiment, controller 116 can configure a length for each of the tension strings 430-444 individually, and each of the tension adjustment assemblies 404-418 can adjust such length accordingly so that the desired geometry of the coil formed by the coil conductor wire 462 is achieved. In this case, the functionality of the tension maintaining assembly 506 is to remove any loose tension string and ensure the desired length of the tension string remains unchanged.

FIG. 6A and FIG. 6B illustrate example configurations of the AGTC of FIG. 4 using different coil geometries, in an example embodiment. More specifically, FIG. 6A illustrates an example geometry 600A of AGTC 400 where the central spool assembly 424 is moved to the upper left corner of the frame 402. FIG. 6B illustrates an example geometry 6008 of AGTC 400 where the central spool assembly 424 is moved to the lower right corner of the frame 402. As illustrated in FIG. 6A and FIG. 6B, different geometries of the AGTC can be configured by moving the central spool assembly 424 to different locations within the frame 402 using drive screws 420 and 422 as well as using different lengths of the tension strings 430-444. In this regard, the geometries 600A and 600B are only examples to illustrate the multiple possibilities of variable geometry of the AGTC which can be achieved using the disclosed techniques.

In an example embodiment, after controller 116 configures the location of the central spool assembly 424 the AGTC 400 geometry or perimeter length of the coil conductor wire can be adjusted by adjusting the lengths of the tension strings 430-444 (as well as constricting or releasing more coil conductor wire via the wire supply assembly 465). Additionally, the voltage supply assembly 464 can be used to adjust the voltage or current of the AGTC 400. In this regard, parameters of the AGTC which can be adjusted based on detected residual magnetic fields or detected nonuniformity of a substrate surface (e.g., a lithographic mask), include the geometry of the coil, the perimeter length of the coil conductor wire, and current through the coil conductor wire.

In an example embodiment, multiple parameters of the AGTC can be adjusted (e.g., periodically/dynamically, during substrate processing) based on sensed residual magnetic fields and/or substrate non-uniformity. For example, both the geometry (or perimeter) of the AGTC as well as the current can be adjusted based on proximity of the AGTC to one or more magnetic field sources (e.g., a hoist that is a source of a residual magnetic field), the strength of the residual magnetic field, direction of the residual magnetic field, etc.

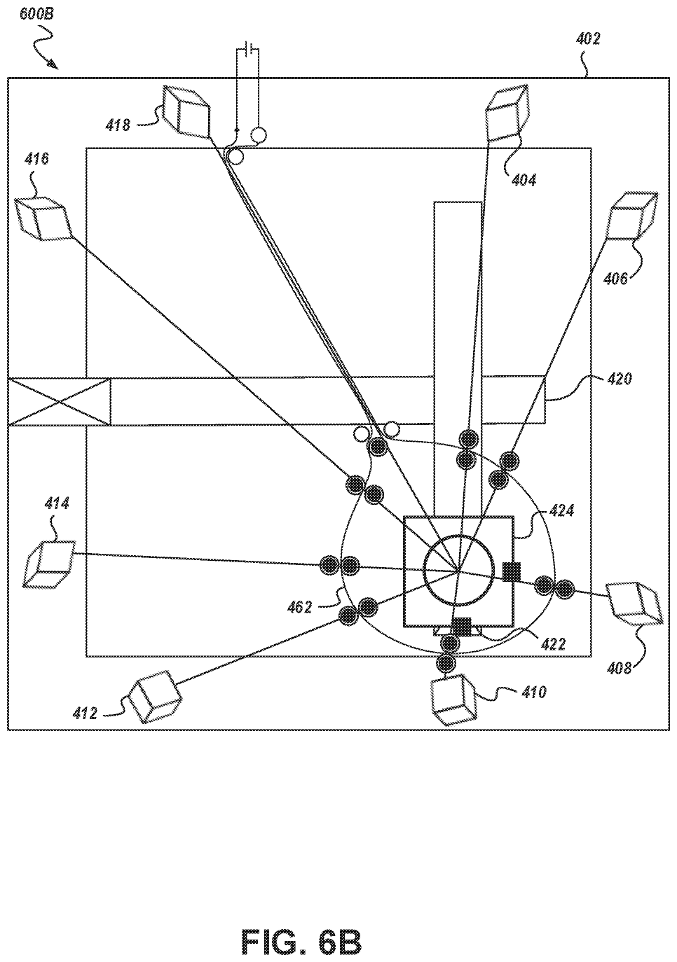

In an example embodiment, one or more supplemental (or trim) magnetic fields can be generated by at least one AGTC using the techniques discussed herein (e.g., as illustrated in FIG. 7A-FIG. 9) to counteract a residual magnetic field (e.g., residual magnetic field 310) that is present within the vacuum chamber 302 or to counteract a non-uniformity of a substrate surface.

FIG. 7A illustrates a perspective view 700A of a vacuum chamber 702 with an AGTC used as a magnetic field source to counteract a residual magnetic field, according to an example embodiment. Referring to FIG. 7A, the vacuum chamber 702 may experience a residual magnetic field 710 (which includes primarily a vertical component Bz) measured at location 708 (which may be within the processing zone of the vacuum chamber). An AGTC 704 (which can be similar to AGTC 400) may be configured to generate a supplemental (or trim) magnetic field 706 within the vacuum chamber 702. The supplemental (or trim) magnetic field is also indicated as Bt 712, having an opposite direction to the direction of the residual magnetic field 710 and a similar magnitude.

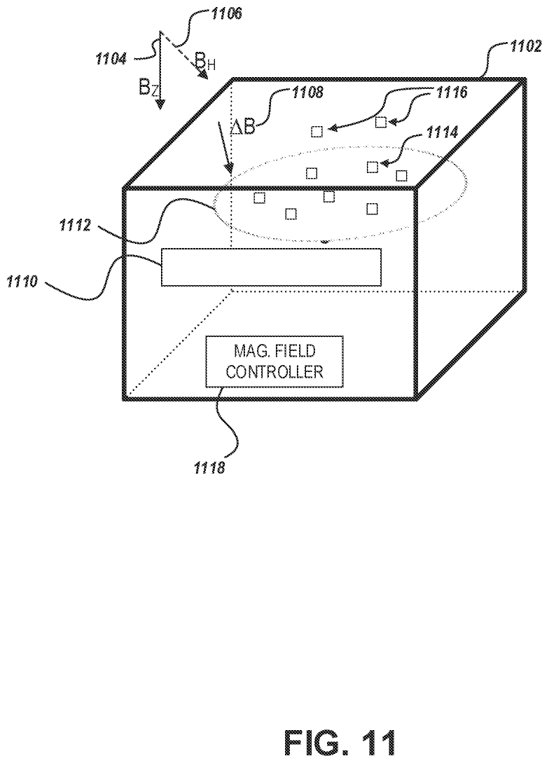

In an example embodiment, the residual magnetic field 710 may be detected and measured by a magnetic field sensor placed at or near location 708. Example magnetic field sensors that can be used to detect residual magnetic fields are illustrated in connection with FIG. 11. Additionally, a magnetic field. controller (e.g., as illustrated in FIG. 11 which can be controller 116) may be used to adjust one or more parameters of the AGTC 704 to adjust the supplemental magnetic field 712. For example, the magnetic field controller may adjust a current (e.g., a direct current (DC)), the geometry, or the perimeter of the AGTC 704, thereby changing the magnitude of the supplemental magnetic field 712.

In some aspects, the current may be adjusted so that the magnitude of the supplemental magnetic field 712 zeros out, the magnitude of the residual magnetic field 710. In other aspects, the magnetic field controller may adjust the current through the AGTC 704 so that the resulting residual magnetic field 710 (after the supplemental magnetic field 712 is applied) achieves a target magnitude and/or direction (e.g., Bfab, a predetermined residual magnetic field magnitude matching the residual magnetic field magnitude in other vacuum chambers associated with a fabrication process (e.g., Bz˜Bfab)).

In an example embodiment, the magnetic field controller may use a sensor (e.g., as illustrated in FIG. 11) to detect a non-uniformity along a surface of a substrate to be processed within the vacuum chamber 702 (e.g., a non-uniformity of a lithographic mask of the substrate); this non-uniformity can be detected before processing or in situ to be communicated to the magnetic field controller. The magnetic field controller may then configure one or more of the parameters of the AGTC 704 resulting in a magnetic field causing a non-uniform etch of the substrate to match the detected non-uniformity in the substrate surface.

FIG. 7B is a side view 70013 of the vacuum chamber of FIG. 7A and illustrates mounting options for the AGTC, according to an example embodiment. Referring to FIG. 7B. In an example embodiment, the AGTC 704 may be mounted internally, within the vacuum chamber 702, and in proximity to the processing zone 714. In an example embodiment, the AGTC 704 may be mounted on a pedestal 718 secured to the top plate 716 of the vacuum chamber 702. In an example embodiment, the AGTC 704 may also be mounted to an inside surface of the vacuum chamber 702 (e.g., a top surface as illustrated in FIG. 7B) via connections 720.

In an example embodiment, the vacuum chamber 702 may be enclosed within a magnetic shield structure such as the magnetic shield structure 200. In an example embodiment, the AGTC 704 may be secured within the magnetic shield structure but outside of the vacuum chamber 702 (e.g., on an internal surface of the magnetic shield structure). In an example embodiment, the AGTC 704 may be placed outside of the magnetic shield structure and the vacuum chamber 702.

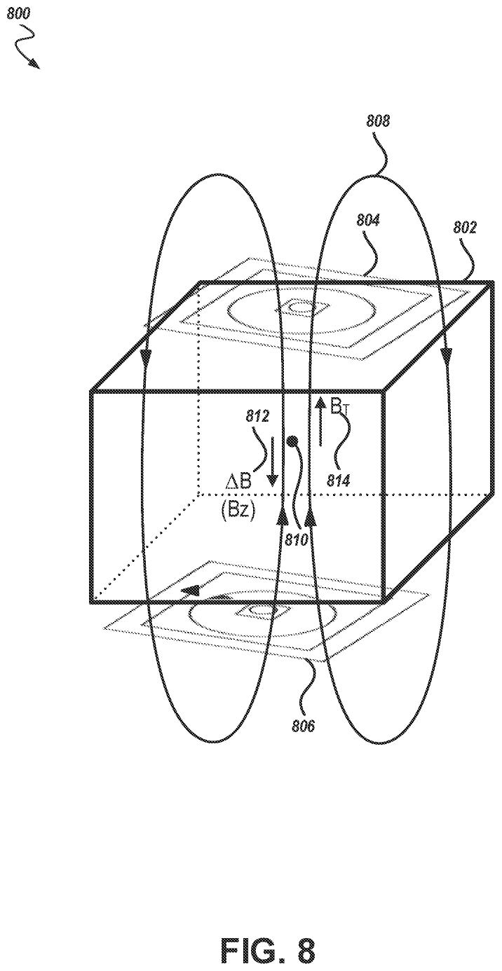

In an example embodiment, multiple AGTCs may be used as magnetic field sources to generate one or more supplemental magnetic fields (e.g., as illustrated in FIG. 8, FIG. 9, and FIG. 10), where each coil may be positioned differently, using the options discussed hereinabove in connection with FIG. 7A and FIG. 78.

FIG. 8 illustrates a perspective view 800 of a vacuum chamber with multiple AGTCs configured as a Helmholtz pair generating a magnetic field to counteract a residual magnetic field, according to an example embodiment. Referring to FIG. 8, the vacuum chamber 802 may experience a residual magnetic field 812 (which includes primarily a vertical component Bz) measured at location 810 (which may be within the processing zone of the vacuum chamber 802). Multiple AGTCs (e.g., two AGTCs) 804 and 806 (which can be similar to AGTC 400) may be configured to generate a supplemental (or trim) magnetic field 808 within the vacuum chamber 802. The supplemental (or trim) magnetic field 808 is also indicated as Bt 814, having an opposite direction to the direction of the residual magnetic field 812 and a similar magnitude.

In an example embodiment, AGTCs 804 and 806 may be configured as a Helmholtz pair. In an example embodiment, the residual magnetic field 812 may be detected and measured by a magnetic field sensor placed at or near location 810. Additionally, a magnetic field controller (e.g., as illustrated in FIG. 11) may be used to adjust one or more parameters of AGTCs 804 and 806, resulting in different characteristics of the supplemental magnetic field 814. For example, the magnetic field controller may adjust a current of the Helmholtz pair of AGTCs 804-806, thereby changing the magnitude of the supplemental magnetic field 814. In some aspects, the current of the AGTCs may be adjusted so that the magnitude of the supplemental magnetic field 814 zeros out the magnitude of the residual magnetic field 812. In other aspects, the magnetic field controller may adjust the current through the Helmholtz pair so that the resulting residual magnetic field 812 (after the supplemental magnetic field 814 is applied) achieves a target magnitude and/or direction. In some aspects, the magnetic coils of the AGTCs 804 and 806 could be more localized than the flat spirals shown in the figure to function as a classic Helmholtz pair.

In an example embodiment, one or more AGTCs can be placed at different locations around the vacuum chamber 802, with each of the AGTCs generating a supplemental field with a pre-configured magnitude and direction of the supplemental field. In some aspects, each of the supplemental magnetic fields can also be configured dynamically (e.g., magnitude and/or direction of each supplemental magnetic field can be set based on periodic measurements of a residual field within or around the vacuum chamber), so that the desired magnitude and/or direction of the residual magnetic field is achieved after the supplemental magnetic fields are activated.

In an example embodiment, the vacuum chamber 802 may be enclosed within a magnetic shield structure such as the magnetic shield structure 200. In an example embodiment, the Helmholtz pair of AGTCs 804 and 806 may be secured within the magnetic shield structure but outside of the vacuum chamber 802 (e.g., on an internal surface of the magnetic shield structure). In an example embodiment, the Helmholtz pair of AGTCs 804 and 806 may be placed outside of the magnetic shield structure and the vacuum chamber 802.

FIG. 9 illustrates a perspective view 900 of a vacuum chamber 902 with multiple AGTCs configured as multiple Helmholtz pairs generating multiple magnetic fields to counteract a residual magnetic field, according to an example embodiment. Referring to FIG. 9, the vacuum chamber 902 may experience a residual magnetic field (not illustrated in FIG. 9). Multiple AGTCs 904-914 (which can be similar to AGTC 400) may be configured to generate supplemental (or trim) magnetic fields 922-926 within the vacuum chamber 902.

In an example embodiment, AGTCs 904-914 may be configured as Helmholtz pairs (e.g., coils 904 and 906 are configured as a first Helmholtz pair along a Z-axis, coils 908 and 910 are configured as a second Helmholtz pair along an X-axis, and coils 912 and 914 are configured as third Helmholtz pair along a Y-axis). In an example embodiment, the residual magnetic field may be detected and measured by a magnetic field sensor placed at or near the processing zone of the vacuum chamber 902. Additionally, a magnetic field controller (e.g., as illustrated in FIG. 11) may be used to adjust one or more characteristics of the supplemental magnetic fields 922, 924, and 926 (having corresponding magnetic field lines 916, 918, and 920). For example, the magnetic field controller may adjust a current of the Helmholtz pairs of AGTCs 904-914, thereby changing the magnitude of each of the supplemental magnetic fields 922, 924, and 926. In some aspects, the current (or other parameters of the AGTCs) may be adjusted so that the magnitude of the supplemental magnetic fields 922-926 zeros out the magnitude of the residual magnetic field. In other aspects, the magnetic field controller may adjust the current through the Helmholtz pairs so that the resulting residual magnetic field (after one or more of the supplemental magnetic fields are applied) achieves a target magnitude and/or direction.

In an example embodiment, the magnetic field controller can use one or more magnetic field sensors to detect the residual magnetic field within the vacuum chamber 902 or to detect a non-uniformity of a substrate surface. The magnetic field controller may then determine how many of the configured Helmholtz pairs of AGTCs can be activated based on the desired direction and/or magnitude of a supplemental magnetic field. For example, if the residual magnetic field is associated with a direction that coincides with the direction of only one of the supplemental magnetic fields 922-926, then only the corresponding Helmholtz pair associated with the matching direction is activated. Additionally, if a direction of the residual magnetic field is a combination of two or more of the directions of the supplemental magnetic fields 922-926, then the corresponding Helmholtz pairs associated with such directions are activated. In an example embodiment, the magnetic field controller may activate one or multiple of the available Helmholtz pairs based on the desired magnitude and/or direction of a resulting magnetic field (e.g., to achieve uniformity of residual magnetic fields between multiple vacuum chambers in a fabrication facility).

In an example embodiment, the vacuum chamber 902 may be enclosed within a magnetic shield structure such as the magnetic shield structure 200. In an example embodiment, the Helmholtz pairs of AGTCs 904-914 may be secured within the magnetic shield structure but outside of the vacuum chamber 902 (e.g., on an internal surface of the magnetic shield structure). In an example embodiment, the Helmholtz pairs of AGTCs 904-914 may be placed outside of the magnetic shield structure and the vacuum chamber 902.

FIG. 10 illustrates a top view 1000 of a vacuum chamber using multiple pairs of AGTCs generating different magnetic fields to counteract a residual magnetic field, according to an example embodiment. Referring to FIG. 10, the vacuum chamber 1002 includes a processing zone 1004 for processing a substrate using CCP (or other techniques). FIG. 10 further illustrates AGTCs 1006, 1008, 1010, and 1012, which may be similar to AGTCs 912, 914, 908, and 910 of FIG. 9, respectively, as well as AGTC 400 of FIG. 4. In an example embodiment, AGTCs 1010 and 1012 may be activated (e.g., as a Helmholtz pair) to generate a horizontal supplemental magnetic field Btb. In an example embodiment, AGTCs 1006 and 1008 may be activated (e.g., as a Helmholtz pair) to generate another horizontal supplemental magnetic field Btz, which may be orthogonal to the horizontal supplemental magnetic field Btb (as illustrated in FIG. 10). In an example embodiment, such horizontal supplemental magnetic fields may be generated separately or together, with the same or different magnitudes, based on a desired magnitude and direction of a resulting residual magnetic field within the vacuum chamber 1002.

FIG. 11 illustrates a vacuum chamber 1102 with different types of magnetic sensors and a magnetic field controller to configure one or more supplemental magnetic fields that counteract a residual magnetic field, according to an example embodiment. Referring to FIG. 11, vacuum chamber 1102 may be shielded (e.g., using magnetic shield structure 200) and exposed to external magnetic fields with a vertical component 1104 and a horizontal component 1106, resulting in a residual magnetic field 1108 within the vacuum chamber 1102.

In an example embodiment, the vacuum chamber 1102 includes a magnetic field controller 1118. The magnetic field controller 1118 can be the same as controller 116. Additionally, the magnetic field controller 1118 comprises suitable circuitry, logic, interfaces, and/or code and is configured to receive magnetic field sensor data or substrate surface non-uniformity data and adjust one or more parameters of at least one AGTC, resulting in a supplemental magnetic field generated by the at least one AGTC. In an example embodiment, a smart wafer 1112 may be loaded within the processing zone of the vacuum chamber 1102 from the opening 1110. The smart wafer 1112 may include a plurality of magnetic field sensors 1114 which are configured to detect and measure residual magnetic fields (e.g., residual magnetic field 1108) after the smart wafer 1112 is placed within the processing zone inside the vacuum chamber 1102. In an example embodiment, the magnetic field controller 1118 may also use one or more standalone magnetic field sensors 1116 to detect and measure residual magnetic fields, such as residual magnetic field 1108, as well as non-uniformity of a substrate surface for purposes of configuring parameters of the at least one AGTC.

In an example embodiment, the magnetic field controller 1118 may use the magnetic field sensors 1114 and/or 1116 to detect the magnitude and direction of the residual magnetic field 1108. The magnetic field controller 1118 may adjust at least one parameter of an AGTC to generate a supplemental magnetic field that counters the residual magnetic field 1108 (or reduces or increases the residual magnetic field to a predetermined value). For example, the magnetic field controller may adjust the current, the geometry, or the perimeter of the AGTC to generate the desired supplemental magnetic field. Additionally, the magnetic field controller 1118 may activate or deactivate one or more AGTCs of a plurality of available AGTCs to achieve zeroing out of a residual magnetic field or a residual magnetic field of desired magnitude and direction to achieve uniformity with other vacuum chambers in a fabrication facility.

The magnetic field controller 1118 may also activate or deactivate one or more AGTCs of a plurality of available AGTCs as well as adjust one or more of the parameters of the activated AGTCs based on a detected non-uniformity of a substrate surface. In this regard, the generated supplemental magnetic field counters the detected surface non-uniformity resulting in a non-uniform etch that matches the surface non-uniformity, contributing to a more uniform surface after the substrate is processed.

In an example embodiment, magnetic field sensors 1114 and/or 1116 may be used for initial measurement so that the magnetic field controller 1118 may perform adjustments resulting in generating a supplemental magnetic field with desired magnitude and direction. Periodic measurements and adjustments may be performed using magnetic field sensors 1114 and/or 1116. In an example embodiment, standalone magnetic field sensors 1116 may be used for automatic (dynamic) measurements and adjustments in the characteristics of the supplemental magnetic fields. In an example embodiment, one magnetic field sensor (or a set of magnetic field sensors) may be used in connection with a single magnetic field source, so that different sensors may be associated with different magnetic field sources. In an example embodiment, the magnetic field controller 1118 may communicate wirelessly with magnetic field sensors 1114 and 1116 to receive the sensor data.

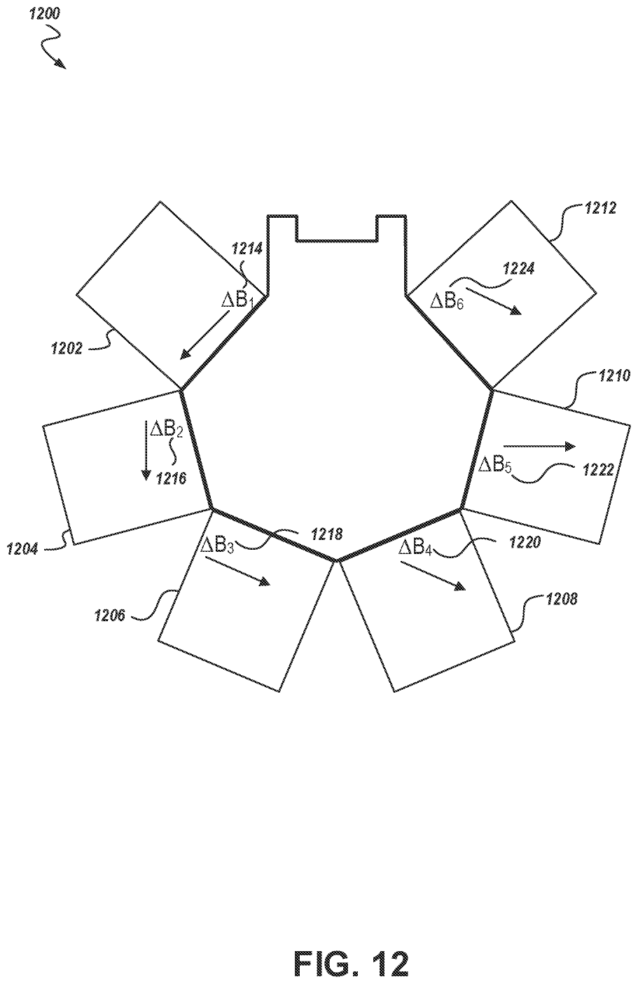

FIC. 12 illustrates an arrangement 1200 of vacuum chambers in a manufacturing facility that can use the disclosed techniques to reduce, zero out, or make uniform multiple residual magnetic fields within the vacuum chambers, according to an example embodiment. Referring to FIG. 12, arrangement 1200 may be located within a semiconductor fabrication facility and may include multiple vacuum chambers such as vacuum chambers 1202, 1204, 1206, 1208, 1210, and 1212. Each of the vacuum chambers may be magnetically shielded and may be exposed to different external magnetic fields, resulting in different residual magnetic fields within each vacuum chamber. More specifically, vacuum chambers 1202, 1204, 1206, 1208, 1210, and 1212 are associated with corresponding residual magnetic fields 1214, 1216, 1218, 1220, 1222, and 1224. In an example embodiment, one or more of the techniques discussed herein may be used to zero out each of the residual magnetic fields within the vacuum chambers or achieve a uniform residual magnetic field of the same magnitude and direction within each of the vacuum chambers.

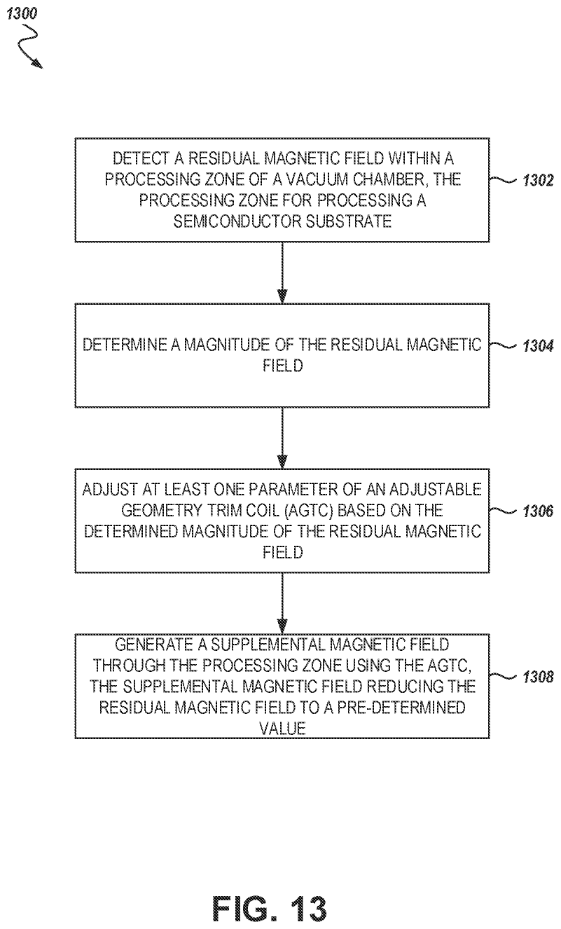

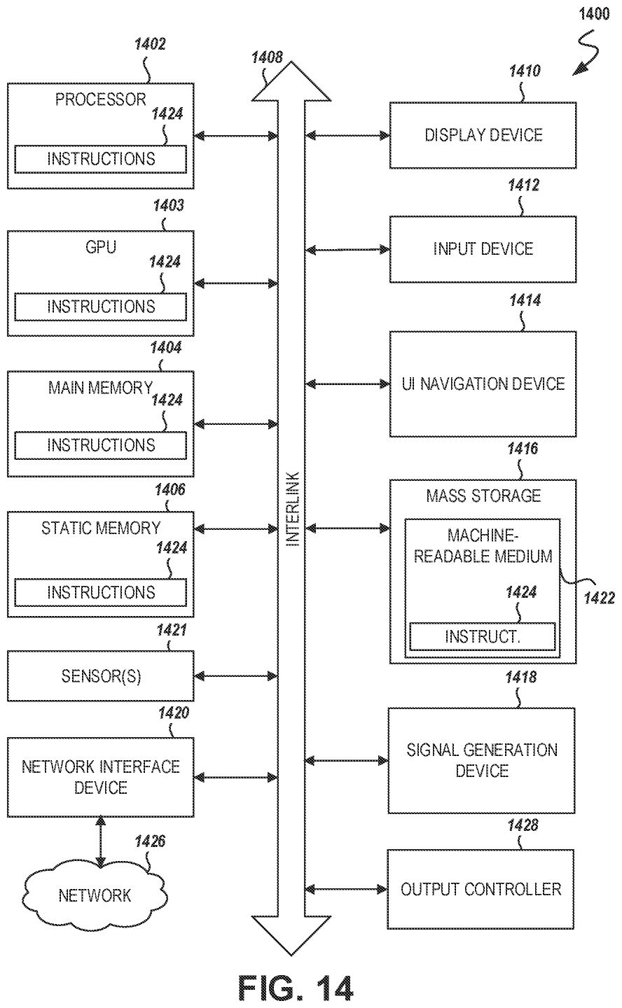

FIG. 13 is a flowchart of a method 1300 for processing a substrate using magnetic fields in semiconductor manufacturing equipment, according to an example embodiment. Method 1300 includes operations 1302, 1304, 1306, and 1308, which may be performed by a magnetic field controller such as magnetic field controller 1118 of FIG. 11, controller 116 of FIG. 1, or processor 1402 of FIG. 14. Referring to FIG. 13, at operation 1302, a residual magnetic field is detected within a processing zone of a vacuum chamber, where the processing zone is used for processing a substrate (e.g., a semiconductor substrate). For example, a residual magnetic field 310 is detected within the processing zone 304 of the vacuum chamber 302. At operation 1304, a magnitude of the residual magnetic field is determined. For example, the magnetic field controller 1118 can determine the magnitude of the residual magnetic field using one or more of the sensors 1114 and 1116. At operation 1306, at least one parameter of an AGTC is adjusted based on the determined magnitude of the residual magnetic field. For example, the magnetic field controller 1118 adjusts the geometry, perimeter, and/or current of the AGTC based on the determined magnitude of the residual magnetic field (e.g., as discussed in connection with FIG. 4-FIG. 10). At operation 1308, a supplemental magnetic field is generated through the processing zone using the configured AGTC, where the supplemental magnetic field reduces the residual magnetic field to a predetermined value (e.g., in zeros out the residual magnetic field or reduces it to a predetermined value).

FIG. 14 is a block diagram illustrating an example of a machine 1400 upon or by which one or more example process embodiments described herein may be implemented or controlled. In alternative embodiments, the machine 1400 may operate as a standalone device or may be connected (e.g., networked) to other machines. In a networked deployment, the machine 1400 may operate in the capacity of a server machine, a client machine, or both in server-client network environments. In an example, the machine 1400 may act as a peer machine in a peer-to-peer (P2P) (or other distributed) network environment. Further, while only a single machine 1400 is illustrated, the term “machine” shall also be taken to include any collection of machines that individually or jointly execute a set (or multiple sets) of instructions to perform any one or more of the methodologies discussed herein, such as via cloud computing, software as a service (SaaS), or other computer cluster configurations.

Examples, as described herein, may include, or may operate by, logic, several components, or mechanisms. Circuitry is a collection of circuits implemented in tangible entities that include hardware (e.g., simple circuits, gates, logic). Circuitry membership may be flexible over time and underlying hardware variability. Circuitries include members that may, alone or in combination, perform specified operations when operating. In an example, the hardware of the circuitry may be immutably designed to carry out a specific operation (e.g., hardwired). In an example, the hardware of the circuitry may include variably connected physical components (e.g., execution units, transistors, simple circuits) including a computer-readable medium physically modified (e.g., magnetically, electrically, by the moveable placement of invariant massed particles) to encode instructions of the specific operation. In connecting the physical components, the underlying electrical properties of a hardware constituent are changed (for example, from an insulator to a conductor or vice versa). The instructions enable embedded hardware (e.g., the execution units or a loading mechanism) to create members of the circuitry in hardware via the variable connections to carry out portions of the specific operation when in operation. Accordingly, the computer-readable medium is communicatively coupled to the other components of the circuitry when the device is operating. In some aspects, any of the physical components may be used in more than one member of more than one circuitry. For example, under operation, execution units may be used in a first circuit of a first circuitry at one point in time and reused by a second circuit in the first circuitry, or by a third circuit in a second circuitry, at a different time.

The machine (e.g., computer system) 1400 may include a hardware processor 1402 (e.g., a central processing unit (CPU), a hardware processor core, or any combination thereof), a graphics processing unit (GPU) 1403, a main memory 1404, and a static memory 1406, some or all of which may communicate with each other via an interlink (e.g., bus) 1408. The machine 1400 may further include a display device 1410, an alphanumeric input device 1412 (e.g., a keyboard), and a user interface (UI) navigation device 1414 (e.g., a mouse). In an example, the display device 1410, alphanumeric input device 1412, and UI navigation device 1414 may be a touch screen display. The machine 1400 may additionally include a mass storage device (e.g., drive unit) 1416, a signal generation device 1418 (e.g., a speaker), a network interface device 1420, and one or more sensors 1421, such as a Global Positioning System (GPS) sensor, compass, accelerometer, or another sensor. The machine 1400 may include an output controller 1428, such as a serial (e.g., universal serial bus (USB)), parallel, or other wired or wireless (e.g., infrared (IR), near field communication (NFC)) connection to communicate with or control one or more peripheral devices (e.g., a printer, card reader).

In an example embodiment, the hardware processor 1402 may be the same as controller 116 and may be configured to perform the functionalities of the magnetic field controller 1118 discussed hereinabove, in connection with at least FIG. 11.

The mass storage device 1416 may include a machine-readable medium 1422 on which is stored one or more sets of data structures or instructions 1424 (e.g., software) embodying or utilized by any one or more of the techniques or functions described herein. The instructions 1424 may also reside, completely or at least partially, within the main memory 1404, within the static memory 1406, within the hardware processor 1402, or within the GPU 1403 during execution thereof by the machine 1400. In an example, one or any combination of the hardware processor 1402, the GPU 1403, the main memory 1404, the static memory 1406, or the mass storage device 1416 may constitute machine-readable media.

While the machine-readable medium 1422 is illustrated as a single medium, the term “machine-readable medium” may include a single medium or multiple media, (e.g., a centralized or distributed database, and/or associated caches and servers) configured to store the one or more instructions 1424.

The term “machine-readable medium” may include any medium that is capable of storing, encoding, or carrying instructions 1424 for execution by the machine 1400 and that cause the machine 1400 to perform any one or more of the techniques of the present disclosure, or that is capable of storing, encoding, or carrying data structures used by or associated with such instructions 1424. Non-limiting machine-readable medium examples may include solid-state memories and optical and magnetic media In an example, a massed machine-readable medium comprises a machine-readable medium 1422 with a plurality of particles having invariant (e.g., rest) mass. Accordingly, massed machine-readable media are not transitory propagating signals. Specific examples of massed machine-readable media may include non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; and CD-ROM and DVD-ROM disks.

The instructions 1424 may further be transmitted or received over a communications network 1426 using a transmission medium via the network interface device 1420.

Implementation of the preceding techniques may be accomplished through any number of specifications, configurations, or example deployments of hardware and software. It should be understood that the functional units or capabilities described in this specification may have been referred to or labeled as components or modules, to more particularly emphasize their implementation independence. Such components may be embodied by any number of software or hardware forms. For example, a component or module may be implemented as a hardware circuit comprising custom very-large-scale integration (VLSI) circuits or gate arrays, off-the-shelf semiconductors such as logic chips, transistors, or other discrete components. A component or module may also be implemented in programmable hardware devices such as field-programmable gate arrays, programmable array logic, programmable logic devices, or the like. Components or modules may also be implemented in software for execution by various types of processors. An identified component or module of executable code may, for instance, comprise one or more physical or logical blocks of computer instructions, which may, for instance, be organized as an object, procedure, or function. Nevertheless, the executables of an identified component or module need not be physically located together but may comprise disparate instructions stored in different locations which, when joined logically together, comprise the component or module and achieve the stated purpose for the component or module.

Indeed, a component or module of executable code may be a single instruction, or many instructions, and may even be distributed over several different code segments, among different programs, and across several memory devices or processing systems. In particular, some aspects of the described process (such as code rewriting and code analysis) may take place on a different processing system (e.g., in a computer in a data center), than that in which the code is deployed (e.g., in a computer embedded in a sensor or robot). Similarly, operational data may be identified and illustrated herein within components or modules and may be embodied in any suitable form and organized within any suitable type of data structure. The operational data may be collected as a single data set or may be distributed over different locations including over different storage devices, and may exist, at least partially, merely as electronic signals on a system or network. The components or modules may be passive or active, including agents operable to perform desired functions.

### ADDITIONAL NOTES & EXAMPLES

Example 1 is a substrate processing apparatus, including a vacuum chamber including a processing zone for processing a substrate; an adjustable geometry trim coil (AGTC) configured to generate a supplemental magnetic field through the processing zone of the vacuum chamber; and a magnetic field controller coupled to the AGTC, the magnetic field controller configured to adjust at least one parameter of the AGTC, causing the supplemental magnetic field to reduce a residual magnetic field within the vacuum chamber to a pre-determined value.

In Example 2, the subject matter of Example 1 includes subject matter where the at least one parameter of the AGTC is at least one of a geometry of the AGTC; a perimeter length of a coil conductor wire forming the AGTC; current through the coil conductor wire; a relative location of the AGTC with respect to a magnetic component; and a position of a length of the coil conductor wire forming the AGTC including magnetic material to geometrically direct, concentrate or shield a magnetic flux from the current through the coil conductor wire.

In Example 3, the subject matter of Example 2 includes, a magnetic field sensor configured to detect the residual magnetic field within the vacuum chamber; wherein the magnetic field sensor is a wafer sensor placed within the processing zone of the vacuum chamber.

In Example 4, the subject matter of Example 3 includes subject matter where the wafer sensor comprises an array of magnetic field sensors configured to measure magnitudes of the residual magnetic field at a plurality of locations within the processing zone; and wherein the magnetic field controller adjusts the at least one parameter of the AGTC based on the measured magnitudes.

In Example 5, the subject matter of Example 4 includes subject matter where the magnetic field controller adjusts the current through the coil conductor wire of the AGTC causing a magnitude of the supplemental magnetic field to match an average magnitude derived from the measured magnitudes of the residual magnetic field at the plurality of locations.

In Example 6, the subject matter of Example 5 includes subject matter where the magnetic field controller adjusts the at least one parameter of the AGTC resulting in the magnitude of the supplemental magnetic field to match the average magnitude, and a direction of the supplemental magnetic field is opposite to a direction of the residual magnetic field.

In Example 7, the subject matter of Examples 1-6 includes subject matter where the AGTC is mounted on a support structure attached to a surface of a top plate of the vacuum chamber.

In Example 8, the subject matter of Examples 1-7 includes, at least another AGTC (e.g., a second AGTC) configured to generate at least another supplemental magnetic field through the processing zone of the vacuum chamber.

In Example 9, the subject matter of Example 8 includes subject matter where one or both of the supplemental magnetic fields and the at least another supplemental magnetic field AGTC are generated with a direction that is opposite a vertical component (Hz) of the residual magnetic field.

In Example 10, the subject matter of Example 9 includes subject matter where the at least another AGTC is configured to generate the at least another supplemental magnetic field with a direction that is opposite a horizontal component (Bh) of the residual magnetic field.

In Example 11, the subject matter of Examples 8-10 includes subject matter where the AGTC and the at least another AGTC are configured as a Helmholtz pair, the Helmholtz pair configured to generate the supplemental magnetic field along a vertical axis or a horizontal axis of the vacuum chamber.

In Example 12, the subject matter of Examples 2-11 includes subject matter where the AGTC further comprises: a plurality of tension adjustment assemblies coupled to a corresponding plurality of tension strings, each tension string of the plurality of tension strings including a perimeter guide roller set for guiding a portion of the coil conductor wire.

In Example 13, the subject matter of Example 12 includes subject matter where the magnetic field controller is configured to adjust a length of one or more of the plurality of tension strings using corresponding ones of the plurality of tension adjustment assemblies, to change the geometry of the AGTC based on the residual magnetic field.

In Example 14, the subject matter of Examples 12-13 includes subject matter where the AGTC comprises a wire supply assembly, and wherein the magnetic field controller is configured to adjust the perimeter length of a coil conductor wire via the wire supply assembly and by adjusting a length of one or more of the plurality of tension strings using corresponding ones of the plurality of tension adjustment assemblies.

In Example 15, the subject matter of Examples 12-14 includes subject matter where the AGTC further comprises a central spool assembly configured to receive one end of each tension string of the plurality of tension strings, with an opposite end of each tension string of the plurality of tension strings being attached to the plurality of tension adjustment assemblies, and where the magnetic field controller is configured to move the central spool assembly along a vertical drive screw or a horizontal drive screw via at least one drive motor to adjust the geometry of the AGTC.

Example 16 is a method for processing a substrate using a vacuum chamber, the method comprising: detecting a residual magnetic field within a processing zone of the vacuum chamber, the processing zone for processing the substrate; determining a magnitude of the residual magnetic field; adjusting at least one parameter of an adjustable geometry trim coil (AGTC) based on the determined magnitude of the residual magnetic field; and generating a supplemental magnetic field through the processing zone of the vacuum chamber using the AGTC, the supplemental magnetic field reducing the residual magnetic field to a pre-determined value.

In Example 17, the subject matter of Example 16 includes subject matter where the at least one parameter of the AGTC is at least one of a geometry of the AGTC, a perimeter length of a coil conductor wire forming the AGTC and current through the coil conductor wire.

In Example 18, the subject matter of Example 17 includes subject matter where determining the magnitude further comprises: determining a magnitude of a vertical component (Bz) of the residual magnetic field and determining a magnitude of a horizontal component (Bh) of the residual magnetic field.

In Example 19, the subject matter of Example 18 includes, configuring the at least one parameter of the AGTC to generate the supplemental magnetic field for reducing the magnitude of the vertical component of the residual magnetic field; and configuring at least another AGTC to generate at least another supplemental magnetic field for reducing the magnitude of the horizontal component of the residual magnetic field.

In Example 20, the subject matter of Examples 18-19 includes subject matter where the substrate is non-processed or post-processed, the method further comprising: detecting a non-uniformity of a metric of the substrate or sub-micron features of the substrate; and adjusting the at least one parameter of the AGTC further based on the detected non-uniformity.

In Example 21, the subject matter of Example 20 includes, adjusting the at least one parameter of the AGTC during the processing of the substrate.

Example 22 is a non-transitory machine-readable storage medium including instructions that, when executed by a machine, cause the machine to perform operations comprising: detecting a residual magnetic field within a processing zone of a vacuum chamber, the processing zone for processing a substrate; determining a magnitude of the residual magnetic field; adjusting at least one parameter of an adjustable geometry trim coil (AGTC) based on the determined magnitude of the residual magnetic field; and generating a supplemental magnetic field through the processing zone of the vacuum chamber using the AGTC, the supplemental magnetic field reducing the residual magnetic field to a pre-determined value.

In Example 23, the subject matter of Example 22 includes subject matter where the at least one parameter of the AGTC is at least one of a geometry of the AGTC, a perimeter length of a coil conductor wire forming the AGTC and current through the coil conductor wire.

In Example 24, the subject matter of Example 23 includes, the operations further comprising: determining a magnitude of a vertical component (Bz) of the residual magnetic field; and determining a magnitude of a horizontal component (Bh) of the residual magnetic field.

In Example 25, the subject matter of Example 24 includes, the operations further comprising: configuring the at least one parameter of the AGTC to generate the supplemental magnetic field for reducing the magnitude of the vertical component of the residual magnetic field, and configuring at least another AGTC to generate at least another supplemental magnetic field for reducing the magnitude of the horizontal component of the residual magnetic field.

Example 26 is at least one machine-readable medium including instructions that, when executed by processing circuitry, cause the processing circuitry to perform operations to implement any of Examples 1-25.

Example 27 is an apparatus comprising means to implement any of Examples 1-25.

Example 28 is a system to implement any of Examples 1-25.

Example 29 is a method to implement any of Examples 1-25.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components for example configurations may be implemented as a combined structure or component. Similarly, structures and functionality presented as a single component may be implemented as separate components. These and other variations, modifications, additions, and improvements fall within the scope of the subject matter herein.

The embodiments illustrated herein are described in sufficient detail to enable those skilled in the art to practice the teachings disclosed. Other embodiments may be used and derived therefrom, such that structural and logical substitutions and changes may be made without departing from the scope of this disclosure. The Detailed Description, therefore, is not to be taken in a limiting sense, and the scope of various embodiments is defined only by the appended claims, along with the full range of equivalents to which such claims are entitled.

The claims may not set forth every feature disclosed herein as embodiments may feature a subset of said features. Further, embodiments may include fewer features than those disclosed in a particular example. Thus, the following claims are hereby incorporated into the Detailed Description, with a claim standing on its own as a separate embodiment.

As used herein, the term “or” may be construed in either an inclusive or exclusive sense. Moreover, plural instances may be provided for resources, operations, or structures described herein as a single instance. Additionally, boundaries between various resources, operations, modules, engines, and data stores are somewhat arbitrary, and particular operations are illustrated in a context of specific illustrative configurations. Other allocations of functionality are envisioned and may fall within the scope of various embodiments of the present disclosure. In general, structures and functionality presented as separate resources in the example configurations mar be implemented as a combined structure or resource. Similarly, structures and functionality presented as a single resource may be implemented as separate resources. These and other variations, modifications, additions, and improvements fall within a scope of embodiments of the present disclosure as represented by the appended claims. The specification and drawings are, accordingly, to be regarded in an illustrative rather than a restrictive sense.

What is claimed is:

1. A substrate processing apparatus, comprising:
a vacuum chamber including a processing zone for processing a substrate;
an adjustable geometry trim coil (AGTC) configured to generate a supplemental magnetic field through the processing zone of the vacuum chamber; and
a magnetic field controller coupled to the AGTC; the magnetic field controller configured to adjust at least one parameter of the AGTC, causing the supplemental magnetic field to reduce a residual magnetic field within the vacuum chamber to a pre-determined value.

2. The apparatus of claim 1, wherein the at least one parameter of the AGTC is at least one of:
a geometry of the AGTC;
a perimeter length of a coil conductor wire forming the AGTC;
a current through the coil conductor wire;
a relative location of the AGTC with respect to a magnetic component; and
a position of a length of the coil conductor wire forming the AGTC including magnetic material to geometrically direct, concentrate or shield a magnetic flux from the current through the coil conductor wire.

3. The apparatus of claim 2, further comprising:
a magnetic field sensor configured to detect the residual magnetic field within the vacuum chamber;
wherein the magnetic field sensor is a wafer sensor placed within the processing zone of the vacuum chamber.

4. The apparatus of claim 3, wherein the wafer sensor comprises an array of magnetic field sensors configured to measure magnitudes of the residual magnetic field at a plurality of locations within the processing zone; and
wherein the magnetic field controller adjusts the at least one parameter of the AGTC based on the measured magnitudes.

5. The apparatus of claim 4, wherein the magnetic field controller adjusts the current through the coil conductor wire of the AGTC causing a magnitude of the supplemental magnetic field to match an average magnitude derived from the measured magnitudes of the residual magnetic field at the plurality of locations.

6. The apparatus of claim 5, wherein the magnetic field controller adjusts the at least one parameter of the AGTC resulting in the magnitude of the supplemental magnetic field to match the average magnitude, and a direction of the supplemental magnetic field is opposite to a direction of the residual magnetic field.

7. The apparatus of claim 1, wherein the AGTC is mounted on a support structure attached to a surface of a top plate of the vacuum chamber.

8. The apparatus of claim 1, further comprising at least another AGTC configured to generate at least another supplemental magnetic field through the processing zone of the vacuum chamber.

9. The apparatus of claim 8, wherein one or both of the supplemental magnetic field and the at least another supplemental magnetic field AGTC are generated with a direction that is opposite a vertical component (Bz) of the residual magnetic field.

10. The apparatus of claim 9, wherein the at least another AGTC is configured to generate the at least another supplemental magnetic field with a direction that is opposite a horizontal component (Bh) of the residual magnetic field.

11. The apparatus of claim 8, wherein the AGTC and the at least another AGTC are configured as a Helmholtz pair, the Helmholtz pair configured to generate the supplemental magnetic field along a vertical axis or a horizontal axis of the vacuum chamber.

12. The apparatus of claim 2, wherein the AGTC further comprises:
a plurality of tension adjustment assemblies coupled to a corresponding plurality of tension strings, each tension string of the plurality of tension strings including a perimeter guide roller set for guiding a portion of the coil conductor wire.

13. The apparatus of claim 12, wherein the magnetic field controller is configured to:
adjust a length of one or more of the plurality of tension strings using corresponding ones of the plurality of tension adjustment assemblies, to change the geometry of the AGTC based on the residual magnetic field.

14. The apparatus of claim 12, wherein the AGTC comprises a wire supply assembly, and wherein the magnetic field controller is configured to:
adjust the perimeter length of the coil conductor wire via the wire supply assembly and by adjusting a length of one or more of the plurality of tension strings using corresponding ones of the plurality of tension adjustment assemblies.

15. The apparatus of claim 12, wherein the AGTC further comprises a central spool assembly configured to receive one end of each tension string of the plurality of tension strings, with an opposite end of each tension string of the plurality of tension strings being attached to the plurality of tension adjustment assemblies, and wherein the magnetic field controller is configured to:
move the central spool assembly along a vertical drive screw or a horizontal drive screw via at least one drive motor to adjust the geometry of the AGTC.

16. A method for processing a substrate using a vacuum chamber, the method comprising:
detecting a residual magnetic field within a processing zone of the vacuum chamber, the processing zone for processing the substrate;
determining a magnitude of the residual magnetic field;
adjusting at least one parameter of an adjustable geometry trim coil (AGTC) based on the determined magnitude of the residual magnetic field; and
generating a supplemental magnetic field through the processing zone of the vacuum chamber using the AGTC, the supplemental magnetic field reducing the residual magnetic field to a pre-determined value.

17. The method of claim 16, wherein the at least one parameter of the AGTC is at least one of a geometry of the AGTC, a perimeter length of a coil conductor wire forming the AGTC, and current through the coil conductor wire.

18. The method of claim 17, wherein determining the magnitude further comprises:
determining a magnitude of a vertical component (Bz) of the residual magnetic field; and
determining a magnitude of a horizontal component (Bh) of the residual magnetic field.

19. The method of claim 18, further comprising:
configuring the at least one parameter of the AGTC to generate the supplemental magnetic field for reducing the magnitude of the vertical component of the residual magnetic field; and
configuring at least another AGTC to generate at least another supplemental magnetic field for reducing the magnitude of the horizontal component of the residual magnetic field.

20. The method of claim 18, wherein the substrate is non-processed or post-processed, the method further comprising:
detecting a non-uniformity of a metric of the substrate or sub-micron features of the substrate; and
adjusting the at least one parameter of the AGTC further based on the detected non-uniformity.

21. The method of claim 20, further comprising:
adjusting the at least one parameter of the AGTC during the processing of the substrate.

22. A machine-readable storage medium including instructions that, when executed by a machine, cause the machine to perform operations comprising:
detecting a residual magnetic field within a processing zone of a vacuum chamber, the processing zone for processing a substrate;
determining a magnitude of the residual magnetic field;
adjusting at least one parameter of an adjustable geometry trim coil (AGTC) based on the determined magnitude of the residual magnetic field; and
generating a supplemental magnetic field through the processing zone of the vacuum chamber using the AGTC, the supplemental magnetic field reducing the residual magnetic field to a pre-determined value.

23. The machine-readable storage medium of claim 22, wherein the at least one parameter of the AGTC is at least one of a geometry of the AGTC, a perimeter length of a coil conductor wire forming the AGTC, and current through the coil conductor wire.

24. The machine-readable storage medium of claim 23, the operations further comprising.
determining a magnitude of a vertical component (Bz) of the residual magnetic field; and
determining a magnitude of a horizontal component (Bh) of the residual magnetic field.

25. The machine-readable storage medium of claim 24, the operations further comprising:
configuring the at least one parameter of the AGTC to generate the supplemental magnetic field for reducing the magnitude of the vertical component of the residual magnetic field; and
configuring at least another AGTC to generate at least another supplemental magnetic field for reducing the magnitude of the horizontal component of the residual magnetic field.
